(19) United States
(12) Patent Application Publication
(10) Pub. No.: US 2026/0160806 A1
(43) Pub. Date: Jun. 11, 2026

(54) SUBSTRATE INSPECTION APPARATUS

(71) Applicant: Samsung Electronics Co., Ltd., Suwon-si (KR)

(72) Inventors: Daesung Jung, Suwon-si (KR); Gyouil Jeong, Suwon-si (KR); Sang Yoon Han, Suwon-si (KR); MyeongOck Ko, Suwon-si (KR); Seongbeom Lee, Suwon-si (KR)

(21) Appl. No.: 19/235,098

(22) Filed: Jun. 11, 2025

(30) Foreign Application Priority Data
Dec. 6, 2024 (KR) 10-2024-0180892

(51) Int. Cl. G01R 31/28

(52) U.S. Cl. CPC G01R 31/2884

(57) ABSTRACT

An example substrate inspection apparatus includes a substrate support unit that fixes a semiconductor substrate such that the upper surface and lower surface of the semiconductor substrate are exposed, an upper inspection unit spaced apart from the upper surface and movable in horizontal and vertical directions, and configured to obtain a first result value relative to an upper electric field from the upper surface, and a lower inspection unit spaced apart from the lower surface and movable in horizontal and vertical directions, and configured to obtain a second result value relative to a lower electric field from the lower surface. From a plurality of measurement values related to the first result value and the second result value, measured while moving in a vertical direction, information on residual charge remaining on the upper surface and lower surface of the semiconductor substrate and inside the semiconductor substrate is extracted.

### CROSS-REFERENCE TO RELATED APPLICATION

This application claims priority to and the benefit of Korean Patent Application No. 10-2024-0180892 filed at the Korean Intellectual Property Office on Dec. 6, 2024, the entire contents of which are incorporated herein by reference.

### BACKGROUND

During a semiconductor manufacturing process such as an oxidation process, an ion implantation process, a photolithography process, an etching process, a chemical mechanical polishing process, and a packaging process, residual charge may occur at the inside and surface of a substrate such as a wafer. To measure the surface charge remaining at the surface of the substrate, Kelvin probe force microscopy (KPFM) is used.

The KPFM uses a non-contact type of high-resolution surface potential measurement technique to measure the residual charge distribution or residual charge amount of the surface of a substrate. The above-mentioned technique is used, for example, as a modification of atomic force microscopy (AFM), and is detecting a potential difference on a surface through probing to map a residual charge distribution.

However, the above-mentioned technique can contaminate a sample or a needle of equipment since there is an inter-equipment contact possibility when the gap between the needle and a substrate is several nm to several tens of nm. Further, the above-mentioned technique can cause the tip of a probe to come into contact with a semiconductor substrate, resulting in a defect, and it only can measure charge on the front side of a substrate.

### SUMMARY

Various methods of manufacturing a substrate by attaching two or more wafers, such as backside power delivery network, high bandwidth memory (HBM), and hybrid bonding, are used in the substrate manufacturing process. To attach two or more wafers, the wafers are subjected to a polishing and cleaning process, and the polishing and cleaning process may leave charge on the surface of each wafer, and the individual wafers are attached in the state where the residual charge is present. When the wafers are subjected to such a process, residual charge may remain not only on the front side or back side of a substrate but also at the interface between the upper wafer and the lower wafer in the substrate and inside the wafers. Further, as semiconductor processes have evolved with various changes, residual charge may remain inside a substrate with depth from the surface inward.

Such residual charge inside a substrate may cause noise when residual charge remaining on the surface is measured, and may affect subsequent transfer operations, the progress of a process, and the result of a process. As such, since the development of semiconductor devices in which a plurality of wafers is stacked is becoming more active, and new equipment and semiconductor processes are being introduced, it is desired to measure the magnitude and distribution of residual charge remaining not only on the front side and back side of a substrate but also inside the substrate.

The present disclosure relates to a substrate inspection apparatus capable of checking information on charge remaining not only on the front side and back side of a substrate but also inside the substrate with respect to a semiconductor device.

In some implementations, a substrate inspection apparatus may include a substrate support unit that fixes a semiconductor substrate such that the upper surface and lower surface of the semiconductor substrate are exposed, an upper inspection unit that is spaced apart from the upper surface and able to move in horizontal and vertical directions, and obtains a result value relative to an upper electric field from the upper surface, and a lower inspection unit that is spaced apart from the lower surface and able to move in horizontal and vertical directions, and obtains a result value relative to a lower electric field from the lower surface, and from a plurality of measurement values related to the result value relative to the upper electric field and the result value relative to the lower electric field, which the upper inspection unit and the lower inspection unit measure while moving in a vertical direction, information on residual charge remaining on the upper surface and lower surface of the semiconductor substrate and inside the semiconductor substrate may be extracted.

In some implementations, a substrate inspection apparatus may include a substrate support unit that fixes a semiconductor substrate such that the upper surface and lower surface of the semiconductor substrate are exposed, an upper inspection unit that is spaced apart from the upper surface and able to move in a horizontal direction, and obtains a result value relative to an upper electric field from the upper surface, a lower inspection unit that is spaced apart from the lower surface and able to move in a horizontal direction, and obtains a result value relative to a lower electric field from the lower surface, a control unit that receives a plurality of measurement values measured from the upper inspection unit and the lower inspection unit, stores them as data, and calculates information on residual charge on the basis of the data, and a simulation data unit that secures simulation data on the basis of predetermined basic information of information on the semiconductor substrate and information on residual charge inside the semiconductor substrate, and information on residual charge remaining on the upper surface and lower surface of the semiconductor substrate and inside the semiconductor substrate may be extracted using data on a surface charge value of the upper surface or the lower surface and the simulation data.

In some implementations, a substrate inspection apparatus may include a substrate support unit that fixes a semiconductor substrate such that the upper surface and lower surface of the semiconductor substrate are exposed, an upper inspection unit that includes an upper probe which is provided so as to be spaced apart from the upper surface of and movable in horizontal and vertical directions, and an upper charge sensor for obtaining a result value relative to an upper electric field, a lower inspection unit that includes a lower probe which is provided so as to be spaced apart from the lower surface and movable in horizontal and vertical directions, and a lower charge sensor for obtaining a result value relative to a lower electric field from the lower surface, a control unit that receives a plurality of measurement values measured from the upper inspection unit and the lower inspection unit, stores them as data, and calculates information on residual charge on the basis of the data, and a simulation data unit that secures simulation data on the basis of predetermined basic information of information on the semiconductor substrate and information on residual charge inside the semiconductor substrate, wherein at least one of the upper inspection unit and the lower inspection unit is provided so as to be able to be separated in a vertical direction, and at least one of the upper inspection unit and the lower inspection unit extracts information on residual charge remaining on the upper surface and lower surface of the semiconductor substrate and inside the semiconductor substrate using data on a surface charge value of the upper surface or the lower surface and the simulation data while the separation distance from the semiconductor substrate is changed.

In some implementations, a substrate inspection apparatus checks information on charge remaining not only on the front side and back side of a substrate but also inside the substrate with respect to a semiconductor device by measuring a result value attributable to an upper electric field and a result value attributable to a lower electric field multiple times by an upper inspection unit and a lower inspection unit moving in a vertical direction and extracting information on residual charge from the plurality of measurement values.

In some implementations, a substrate inspection apparatus includes a simulation data unit to check information on charge remaining not only on the front side and back side of a substrate but also inside the substrate with respect to a semiconductor device, using measurement values measured by an inspection unit and simulation data.

### BRIEF DESCRIPTION OF THE DRAWINGS

FIG. 1 is a perspective view illustrating an example of a substrate inspection apparatus.

FIG. 2 is a perspective view illustrating an example of an upper inspection unit and an example of a lower inspection unit of FIG. 1.

FIG. 3 is an example enlarged view illustrating part A of FIG. 2.

FIG. 4 is a block diagram illustrating an example of an upper charge sensor of the upper inspection unit.

FIG. 5 is an example cross-sectional view taken along line B-B′ of FIG. 2.

FIGS. 6, 7, and 8 are schematic views illustrating an example of an operation of the substrate inspection apparatus.

FIGS. 9, 10, and 11 are schematic views illustrating an example of an operation of a substrate inspection apparatus.

FIGS. 12 and 13 are views illustrating an example of an operation of a substrate inspection apparatus.

FIGS. 14 and 15 are schematic views illustrating an example of an operation of a substrate inspection apparatus.

FIGS. 16, 17, and 18 are views illustrating an example of an operation of a substrate inspection apparatus.

FIGS. 19 and 20 are schematic views illustrating an example of an operation of the substrate inspection apparatus of FIG. 16.

FIG. 21 is a perspective view illustrating an example of the upper inspection unit and lower inspection unit of FIG. 1.

FIGS. 22 and 23 are schematic views illustrating an example of the substrate inspection apparatus of FIG. 21.

FIGS. 24, 25, and 26 are example schematic cross-sectional views taken along line C-C′ of FIG. 21 and illustrating an example of the operation of the substrate inspection apparatus.

### DETAILED DESCRIPTION

In the following detailed description, only certain implementations of the present disclosure have been shown and described, simply by way of illustration. The present disclosure can be variously implemented and is not limited to the following implementations.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Furthermore, the terms such as “unit” or “module”, the suffix “-or” or “-er”, etc., used in this specification are terms for indicating constituent elements for performing at least one function or operation, and these constituent elements may be implemented with hardware or software, or may be implemented with a combination of hardware and software

Moreover, a plurality of “units”, a plurality of “-ors” or “-ers”, or a plurality of “modules” may be integrated into at least one module and implemented as at least one processor, except for “units”, “-ors”, “ers”, or “modules” required to be implemented with specific hardware.

In this specification, “transmission” or “provision” may include indirect transmission or provision via another device or by use of a bypass in addition to direct transmission or provision.

Expressions written in the singular forms in this specification can be comprehended as the singular forms or plural forms unless clear expressions such as “a”, “an”, or “single” are used.

Hereinafter, implementations of the present disclosure will be described in detail such that those skilled in the art can easily realize them. However, the present disclosure may be implemented in various different forms, and is not limited to the implementations to be described herein.

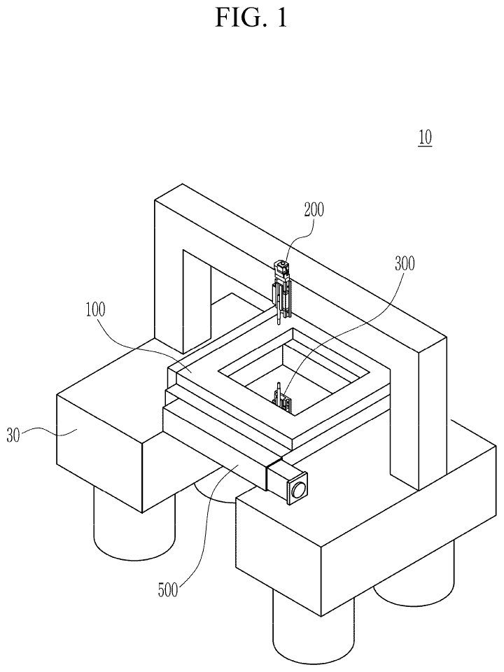

FIG. 1 is a perspective view illustrating an example of a substrate inspection apparatus.

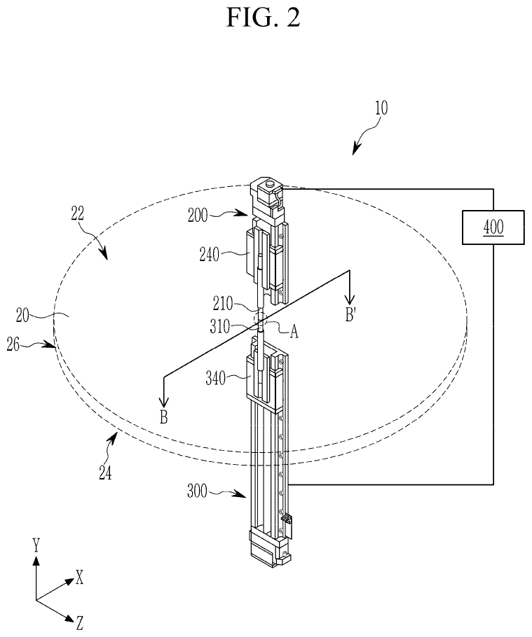

FIG. 2 is a perspective view illustrating an example of an upper inspection unit and an example of a lower inspection unit of FIG. 1.

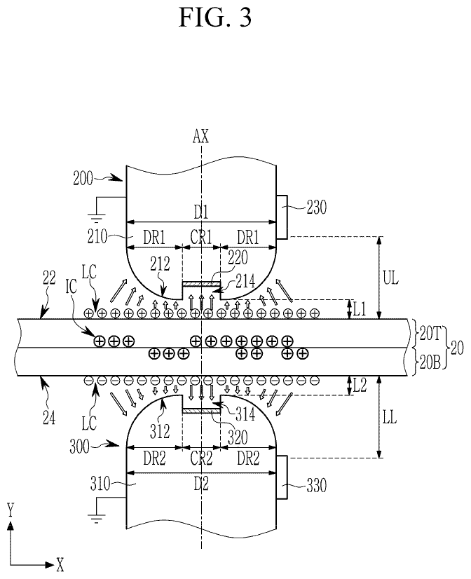

FIG. 3 is an example enlarged view illustrating part A of FIG. 2.

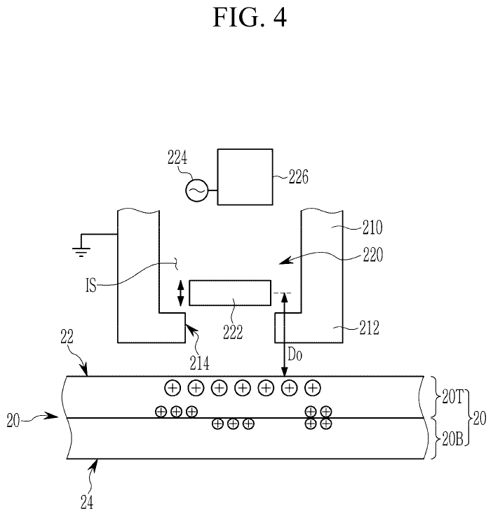

FIG. 4 is a block diagram illustrating an example of an upper charge sensor of the upper inspection unit.

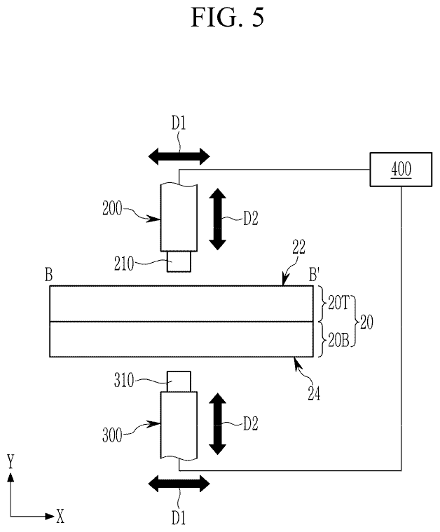

FIG. 5 is an example cross-sectional view taken along line B-B′ of FIG. 2.

Referring to FIGS. 1 to 5, a substrate inspection apparatus 10 may include a substrate support unit 100 that fixes a semiconductor substrate, an upper inspection unit 200 that is disposed above a semiconductor substrate 20 so as to be spaced apart from the semiconductor substrate, and a lower inspection unit 300 that is disposed under the semiconductor substrate 20 so as to be spaced apart from the semiconductor substrate 20. The substrate inspection apparatus 10 may include a table 30 for fixing the substrate support unit 100, the upper inspection unit 200, and the lower inspection unit 300 on the ground.

In some implementations, the substrate inspection apparatus 10 may measure the surface charge LC and internal charge IC of the semiconductor substrate 20 from the semiconductor substrate. The surface charge LC may cause an electrical effect, such as electrostatic particle adsorption, electrostatic discharge (ESD), or arcing, on the semiconductor substrate 20. The surface charge LC may cause the electrical effect on the semiconductor substrate 20, thereby causing a defect inside the semiconductor substrate 20. Surface charge LC may cause a failure such as wafer sticking in which a wafer sticks to an electrostatic chuck.

After two or more semiconductor substrates are subjected to a cleaning process, in a process of bonding them, internal charge IC may occur. In a method of bonding the two or more semiconductor substrates, as a result of a process on each substrate, charge may remain on the surface. When the wafers with residual surface charge are bonded to each other, the charge remains between the interfaces of substrates and inside the substrates. The internal charge may remain inside the substrate consisting of the plurality of substrates stacked, thereby affecting subsequent transfer operations, the progress of a process, and the result of a process, and causing measurement value errors when the surface charge is measured by the substrate inspection apparatus 10. For example, the semiconductor substrate 20 of the present disclosure may include an upper substrate 20T and a lower substrate 20B, and may include surface charge LC which is positioned on the surface, and internal charge IC which is positioned around the interface of the upper substrate 20T and the lower substrate 20B.

The substrate inspection apparatus 10 may extract information on residual charge of the semiconductor substrate 20 from data on a plurality of measurement values which is measured from the semiconductor substrate 20 depending on the surface charge LC and the internal charge IC between semiconductor manufacturing processes which are consecutively performed. The substrate inspection apparatus 10 may measure the surface charge LC and internal charge IC of the semiconductor substrate 20 between semiconductor manufacturing processes such as an oxidation process, a photolithography process, a deposition process, a cleaning process, a development process, or a package process, and interpret information on them. The substrate inspection apparatus 10 may measure the surface charge LC and the internal charge IC between the semiconductor manufacturing processes as described above, thereby improving the reliability of the semiconductor device.

The substrate support unit 100 may be a member which fixes the semiconductor substrate 20. Specifically, the substrate support unit 100 may be a member which fixes the semiconductor substrate 20 such that the upper surface and lower surface of the semiconductor substrate 20 are exposed. In some implementations, the substrate support unit 100 may temporarily fix the semiconductor substrate 20. During the process in which the surface charge is measured, the substrate support unit 100 may stably support the semiconductor substrate 20. The substrate support unit 100 may be fixed on the table 30.

The substrate support unit 100 may fix the outer surface 26 of the semiconductor substrate 20. For example, the outer surface 26 may be the outer side wall surface of the semiconductor substrate 20. Since the substrate support unit 100 fixes the outer surface 26 of the semiconductor substrate 20, the substrate support unit 100 may expose the upper surface 22 and lower surface 24 of the semiconductor substrate 20 simultaneously. Since the substrate support unit 100 exposes the upper surface 22 and lower surface 24 of the semiconductor substrate 20 simultaneously, the upper inspection unit 200 and the lower inspection unit 300 may measure the result values attributable to electric fields from the upper surface 22 and lower surface 24 of the semiconductor substrate 20 simultaneously. In this case, the substrate support unit 100 may support not only the side surface of the semiconductor substrate 20 but also at least a portion of the lower surface of the semiconductor substrate 20.

The substrate support unit 100 may include a plurality of vacuum inlet lines which is formed at the inner surface and applies a vacuum pressure for fixing the semiconductor substrate 20, and a plurality of vacuum holes which is connected to the vacuum inlet lines, respectively, and applies the vacuum pressure. The substrate support unit 100 may be made of a material having sufficient strength and rigidity to withstand the vacuum pressure. The vacuum inlet lines may be connected to a vacuum generator which applies the vacuum pressure, and receive the vacuum pressure. For example, the plurality of vacuum holes may be arranged along the inner surface.

As described above, the substrate support unit 100 may expose the upper surface 22 and lower surface 24 of the semiconductor substrate 20 simultaneously. Since the upper surface 22 and lower surface 24 of the semiconductor substrate 20 are simultaneously exposed, the upper inspection unit 200 and the lower inspection unit 300 may measure a result value attributable to an upper electric field and a result value attributable to a lower electric field from the upper surface 22 and lower surface 24 of the semiconductor substrate 20 through an upper charge sensor 220 and a lower charge sensor 320, respectively.

Since the result value attributable to the upper electric field and the result value attributable to the lower electric field are simultaneously measured, during the measuring process, a potential change due to the mutual influence of the upper surface charge, the lower surface charge, and residual charge remaining inside the semiconductor substrate 20 which occurs between the upper surface 22 and the lower surface 24 can be reflected, and the accuracy of the result value attributable to the upper electric field and the result value attributable to the lower electric field may increase.

The upper inspection unit 200 may measure the result value of the semiconductor substrate 20 attributable to the upper electric field. Specifically, the upper inspection unit 200 may measure a result value based on at least one of the upper surface charge remaining on the upper surface 22 of the semiconductor substrate 20, the residual charge remaining inside the semiconductor substrate 20, and the lower surface charge remaining on the lower surface 24 of the semiconductor substrate 20. More specifically, the result value attributable to the upper electric field may refer to a result value derived according to the interaction between the surface charge and the residual charge.

The upper inspection unit 200 may include an upper probe 210 having a first tip 212, and the upper charge sensor 220 for measuring the result value attributable to the upper electric field from the upper surface 22 of the semiconductor substrate 20. The upper inspection unit 200 may further include an upper distance sensor 230 which measures an upper separation distance UL from the upper surface 22 of the semiconductor substrate 20. The upper inspection unit 200 may further include an upper vertical driver 240 which moves the upper probe 210 in the vertical direction.

The upper probe 210 may have a rod shape extending in the vertical direction above the semiconductor substrate 20. The upper probe 210 may be provided such that the first tip 212 faces the upper surface 22 of the semiconductor substrate 20 above the semiconductor substrate 20. The upper probe 210 may move in the horizontal direction on the upper surface 22 of the semiconductor substrate 20.

The upper probe 210 may be grounded from the ground. Since the upper probe 210 is grounded from the ground, the upper charge formed on the upper surface 22 of the semiconductor substrate 20 may have an upper potential difference from the first tip 212 of the upper probe 210. The upper charge may generate an electrical reaction with the first tip 212 of the upper probe 210 due to the upper potential difference. The upper charge may include charge present in a portion having a predetermined depth from the upper surface of the semiconductor substrate 20. For example, the upper charge may be charge present at a depth of 200 μm from the upper surface.

The first tip 212 of the upper probe 210 may have a first center region CR1, and a first dummy region DR1 which surrounds the first center region CR1. The first tip 212 of the upper probe 210 may generate the electrical reaction with the upper charge of the semiconductor substrate 20 on the first dummy region DR1.

The first tip 212 of the upper probe 210 may have a preset curvature on the first dummy region DR1. When the upper probe 210 moves on the upper surface 22 of the semiconductor substrate 20, the upper probe 210 can prevent damage to the semiconductor substrate 20 by the preset curvature. Since the first tip 212 of the upper probe 210 has the preset curvature, when the first tip 212 collides with the semiconductor substrate 20 in which a warpage phenomenon has occurred, the damage can be alleviated. For example, the preset curvature may be in a range from 1 mm to 100 mm.

The upper charge sensor 220 may obtain an upper charge sensing value (for example, an amount of charge, electrical field strength, or a potential difference) from the upper surface 22 of the semiconductor substrate 20. The upper charge sensor 220 may generate the electrical reaction with the upper charge formed on the upper surface 22 of the semiconductor substrate 20. For example, the upper charge sensor 220 may have a capacitor structure which may constitute an upper capacitor with the semiconductor substrate which is an object, and an actuator 224 which may modulate the capacitance of the upper capacitor, and the upper charge sensor 220 may obtain electrical field strength or a potential difference relative to the upper charge through the upper capacitor. From the electrical field strength or potential difference obtained by the upper charge sensor 220, the upper charge value may be calculated.

The upper charge sensor 220 may be provided on the first center region CR1 on the first tip 212 of the upper probe 210. Since the first tip 212 of the upper probe 210 generates the electrical reaction with the upper charge on the first dummy region DR1, the upper charge sensor 220 may obtain the upper charge sensing value with respect to the upper charge positioned on the first center region CR1. Since the upper charge sensor 220 obtains the upper charge sensing value on the first center region CR1, the spatial resolving power of the upper charge sensor 220 can be improved. Since the spatial resolving power of the upper charge sensor 220 is improved, the upper charge sensor 220 can obtain the upper charge value from a local region.

The upper probe 210 may have a first cavity 214 which is provided on the first center region CR1 of the first tip 212. The upper charge sensor 220 may be provided in the first cavity 214. Since the upper charge sensor 220 is provided in the first cavity 214, the upper charge sensor 220 may obtain the upper charge sensing value with respect to the upper charge positioned on the first center region CR1. The upper charge sensor 220 may obtain the upper charge sensing value from the local region through the first cavity 214.

The upper charge sensor 220 may improve the spatial resolving power by the first dummy region DR1. The upper charge sensor 220 may improve the spatial resolving power by the first cavity 214. The spatial resolving power may be such a degree that it is possible to obtain the upper charge sensing value from the upper charge in the local region.

The first tip 212 of the upper probe 210 may have a first diameter D1. The upper probe 210 may move in the horizontal direction without limitation due to the first diameter D1. The upper probe 210 may sufficiently generate the electrical reaction with the upper charge on the first dummy region DR1 due to the first diameter D1. The first diameter D1 may be within an optimized diameter range for the upper charge sensor 220 to obtain the upper charge sensing value. For example, the first diameter D1 may be within a range from 1 mm to 30 mm.

The upper distance sensor 230 may obtain the upper separation distance UL from the upper surface 22 of the semiconductor substrate 20. The upper distance sensor 230 may calculate the separation distance of the first tip 212 from the upper surface 22 of the semiconductor substrate 20 on the basis of the upper separation distance UL. Alternatively, the upper distance sensor 230 may calculate the distance of the upper distance sensor 230 from the upper surface 22 of the semiconductor substrate 20 on the basis of the upper separation distance UL.

For example, the upper distance sensor 230 may include a confocal chromatic sensor, an interferometric displacement sensor, a laser distance sensor, etc. The upper distance sensor 230 may accurately calculate the upper separation distance UL even when light is reflected from the upper surface 22 of the semiconductor substrate 20.

The upper vertical driver 240 may move the upper probe 210 in the vertical direction. The upper vertical driver 240 may move the upper charge sensor 220 and the upper distance sensor 230, which are provided on the upper probe 210, in the vertical direction.

The upper vertical driver 240 may finely adjust the height of the upper probe 210 on the basis of the upper separation distance UL calculated by the upper distance sensor 230. Specifically, the upper vertical driver 240 may separate the first tip 212 from the upper surface 22 of the semiconductor substrate 20 by a separation distance TH1 which is a first distance. When the first tip 212 is positioned within the set separation distance TH1, the upper vertical driver 240 may stop moving the upper probe 210. This is a nonrestrictive example, and the separation distance TH1 may be variously adjusted as will be described below.

The lower inspection unit 300 may measure the result value of the semiconductor substrate 20 attributable to the lower electric field. Specifically, the lower inspection unit 300 may measure a result value based on at least one of the upper surface charge remaining on the upper surface 22 of the semiconductor substrate 20, the residual charge remaining inside the semiconductor substrate 20, and the lower surface charge remaining on the lower surface 24 of the semiconductor substrate 20. More specifically, the result value attributable to the lower electric field may refer to a result value derived according to the interaction between the surface charge and the residual charge.

The lower inspection unit 300 may include a lower probe 310 having a second tip 312, and a lower charge sensor 320 for measuring the result value attributable to the lower electric field from the lower surface 24 of the semiconductor substrate 20. The lower inspection unit 300 may further include a lower distance sensor 330 which measures a lower separation distance LL from the lower surface 24 of the semiconductor substrate 20. The lower inspection unit 300 may further include a lower vertical driver 340 which moves the lower probe 310 in the vertical direction.

The lower probe 310 may have the rod shape extending in the vertical direction above the semiconductor substrate 20. The lower probe 310 may be provided such that the second tip 312 faces the lower surface 24 of the semiconductor substrate 20 on the semiconductor substrate 20. The lower probe 310 may move in the horizontal direction on the lower surface 24 of the semiconductor substrate 20.

The lower probe 310 may be grounded from the ground. Since the lower probe 310 is grounded from the ground, the lower charge formed on the lower surface 24 of the semiconductor substrate 20 may have a lower potential difference from the second tip 312 of the lower probe 310. The lower charge may generate an electrical reaction with the second tip 312 of the lower probe 310 due to the lower potential difference. The lower charge may include charge present at a portion of the semiconductor substrate 20 having a predetermined depth from the lower surface. For example, the lower charge may be charge present at a depth of 200 μm from the lower surface.

Further, the upper probe 210 may have a center region CR1, and a dummy region DR1 which surrounds the center region CR1, and the lower probe 310 may have a center region CR2, and a dummy region DR2 which surrounds the center region CR2. Since the upper charge sensor 220 and the lower charge sensor 320 are provided on the center regions CR1 and CR2, respectively, the spatial resolving power can be improved. Since the spatial resolving power is improved, the upper charge sensor 220 and the lower charge sensor 320 can accurately measure the result value relative to the upper electric field and the result value relative to the lower electric field from the local region.

The second tip 312 of the lower probe 310 may have the second center region CR2, and the second dummy region DR2 which surrounds the second center region CR2. The second tip 312 of the lower probe 310 may generate the electrical reaction with the lower charge of the semiconductor substrate 20 on the second dummy region DR2.

The second tip 312 of the lower probe 310 may have the preset curvature on the second dummy region DR2. When the lower probe 310 moves on the lower surface 24 of the semiconductor substrate 20, the lower probe 310 can prevent damage to the semiconductor substrate 20 by the preset curvature. Since the second tip 312 of the lower probe 310 has the preset curvature, when the second tip 312 collides with the semiconductor substrate 20 in which a warpage phenomenon has occurred, the damage can be alleviated. For example, the preset curvature may be in a range from 1 mm to 100 mm. The curvature of the tip of the lower probe may be determined in view of the degree of warpage of the semiconductor substrate.

The lower charge sensor 320 may obtain a lower charge sensing value (for example, an amount of charge, electrical field strength, or a potential difference) from the lower surface 24 of the semiconductor substrate 20. The lower charge sensor 320 may generate the electrical reaction with the lower charge formed on the lower surface 24 of the semiconductor substrate 20. For example, the lower charge sensor 320 may have a capacitor structure which may constitute a lower capacitor with the semiconductor substrate which is an object, and an actuator which may modulate the capacitance of the lower capacitor, and the lower charge sensor 320 may obtain the lower potential difference relative to the lower charge through the upper capacitor. From the electrical field strength or potential difference obtained by the lower charge sensor 320, the lower charge value may be calculated.

The lower charge sensor 320 may be provided on the second center region CR2 on the second tip 312 of the lower probe 310. Since the second tip 312 of the lower probe 310 generates the electrical reaction with the lower charge on the second dummy region DR2, the lower charge sensor 320 may obtain the lower charge sensing value with respect to the lower charge positioned on the second center region CR2. Since the lower charge sensor 320 obtains the lower charge sensing value on the second center region CR2, the spatial resolving power of the lower charge sensor 320 can be improved. Since the spatial resolving power of the lower charge sensor 320 is improved, the lower charge sensor 320 can obtain the lower charge sensing value from a local region.

The lower probe 310 may have a second cavity 314 which is provided on the second center region CR2 of the second tip 312. The lower charge sensor 320 may be provided in the second cavity 314. Since the lower charge sensor 320 is provided in the second cavity 314, the lower charge sensor 320 may obtain the lower charge sensing value with respect to the lower charge positioned on the second center region CR2. The lower charge sensor 320 may obtain the lower charge value from the local region through the second cavity 314.

The lower charge sensor 320 may improve the spatial resolving power by the second dummy region DR2. The lower charge sensor 320 may improve the spatial resolving power by the second cavity 314. The spatial resolving power may be such a degree that it is possible to obtain the lower charge sensing value from the lower charge in the local region.

The upper probe 210 may include a housing structure having an accommodation space IS for accommodating at least a portion of the upper charge sensor 220. The housing structure may be a shielding structure which covers at least a portion of the upper charge sensor 220 in the accommodation space IS. The housing structure may contain a metal material such as stainless steel. The upper charge sensor 220 may include a vibrating capacitive sensor.

For example, the upper charge sensor 220 may include a vibrating electrode type field meter. A sensing electrode 222 of the upper charge sensor 220 is exposed through the first cavity 214 of the upper probe 210, and the exposed sensing electrode 222 and the upper surface 22 of the semiconductor substrate 20 facing it may be modeled as a parallel-plate capacitor. The sensing electrode 222 may be vibrated in a direction orthogonal to the upper surface 22 of the semiconductor substrate 20 by the actuator 224, and current I which flows through the sensing electrode 222 may be proportional to the value of the potential difference present on the upper surface 22 of the semiconductor substrate 20. The current I which flows through the sensing electrode 222 may be expressed by the following Expression (1).

$$\begin{matrix}I = U \cdot \frac{dC}{dt} \\ = U \cdot \frac{d}{dt} ( \frac{{ϵϵ}_{0} A}{{D}_{0} + {D}_{1} sin ( ω t )} ) \\ = \cdot U \cdot {ϵϵ}_{0} A \cdot \frac{{D}_{1} ω cos ( ω t )}{{[ {D}_{0} + {D}_{1} min ( ω t ) ]}^{2}}\end{matrix} \qquad Expression ( 1 )$$

Here, U is the potential difference (in V) between the surface which is tested and the vibrating sensing electrode, D₀ is the distance (in m) between the sensing electrode in a stationary state and the surface which is tested, D₁ is the amplitude (in m) of vibration, w is the vibration frequency (ω=2πf) (in rad/s), A is the cross-sectional area (in m²) of the sensing electrode, ε is the relative permittivity of the medium between the sensing electrode and the surface which is being tested (in the case of air, about 1), and ε₀ is the electric permittivity of vacuum (8.85×10⁻¹² F/m).

The current I which flows through the sensing electrode 222 may be amplified and demodulated by a sensing circuit unit 234 including a phase-sensitive demodulator, thereby generating voltage proportional to the amplitude of the current. The generated voltage obtained by the vibrating capacitive sensor of the upper inspection unit 200 may be used to calculate the upper charge value.

Alternatively, the upper charge sensor 220 may include a stationary electrode type field meter. The sensing electrode of the upper charge sensor 220 may be fixed so as to be exposed through the first cavity 214 of the upper probe 210, and the exposed sensing electrode and the upper surface 22 of the semiconductor substrate 20 facing it may be modeled as a parallel-plate capacitor. On the sensing electrode, an aperture modulation unit may be provided. The aperture modulation unit may include a plurality of aperture plates which defines an aperture which exposes a portion of the surface of the sensing electrode. The aperture plates may be vibrated in a direction parallel with the surface of the sensing electrode by an actuator to change the aperture area of the aperture according to the vibration frequency. The aperture plates may be grounded, and as the aperture area is changed, an electric field which is applied to the sensing electrode through the aperture may be changed, whereby the current which flows through the sensing electrode may be changed. The current which flows through the sensing electrode or the potential difference may be detected to calculate the upper charge value.

Similar to the upper probe 210, the lower probe 310 may include a housing structure having an accommodation space for accommodating at least a portion of the lower charge sensor 320. The housing structure may be a shielding structure which covers at least a portion of the lower charge sensor 320 in the accommodation space. The housing structure may contain a metal material such as stainless steel. The lower charge sensor 320 may include a vibrating capacitive sensor. For example, the lower charge sensor 320 may include a vibrating electrode type field meter or a stationary electrode type field meter.

The second tip 312 of the lower probe 310 may have a second diameter D2. The lower probe 310 may move in the horizontal direction without limitation due to the second diameter D2. The lower probe 310 may sufficiently generate the electrical reaction with the lower charge on the second dummy region DR2 due to the second diameter D2. The second diameter D2 may be within an optimized diameter range for the lower charge sensor 320 to obtain the lower charge sensing value. For example, the second diameter D2 may be within a range from 1 mm to 30 mm.

The lower distance sensor 330 may obtain the lower separation distance LL from the lower surface 24 of the semiconductor substrate 20. The lower distance sensor 330 may calculate the distance of the second tip 312 from the lower surface 24 of the semiconductor substrate 20 on the basis of the lower separation distance LL. Alternatively, the lower distance sensor 330 may calculate the distance of the lower distance sensor 330 from the lower surface 24 of the semiconductor substrate 20 on the basis of the lower separation distance LL. For example, the lower distance sensor 330 may include a confocal chromatic sensor, an interferometric displacement sensor, a laser distance sensor, etc.

The lower vertical driver 340 may move the lower probe 310 in the vertical direction. The lower vertical driver 340 may move the lower charge sensor 320 and the lower distance sensor 330, which are provided on the lower probe 310, in the vertical direction.

The lower vertical driver 340 may finely adjust the height of the lower probe 310 on the basis of the lower separation distance LL calculated by the lower distance sensor 330. Specifically, the lower vertical driver 340 may separate the second tip 312 so as to have the separation distance TH1 from the lower surface 24 of the semiconductor substrate 20. When the second tip 312 is positioned within the set separation distance TH1, the lower vertical driver 340 may stop the lower probe 310. This is a nonrestrictive example, and the separation distance TH1 may be variously adjusted as will be described below. As described above, the upper probe 210 and the lower probe 310 may be finely adjusted and vertically moved toward the semiconductor substrate 20 by the upper vertical driver 240 and the lower vertical driver 340.

In some implementations, the substrate inspection apparatus 10 may include a control unit 400. The control unit 400 may be a member which controls the substrate inspection apparatus 10. Specifically, the control unit 400 may be a member which controls the substrate support unit 100, the upper inspection unit 200, and the lower inspection unit 300 in the substrate inspection apparatus 10.

In some implementations, the control unit 400 may transmit control signals to the upper inspection unit 200 and the lower inspection unit 300. Specifically, the control unit 400 may receive the obtained result value attributable to the upper electric field, from the upper inspection unit 200, and receive the obtained result value attributable to the lower electric field, from the lower inspection unit 300. The result value attributable to the upper electric field and the result value attributable to the lower electric field may be the values measured by the upper charge sensor 220 and the lower charge sensor 320.

In some implementations, the control unit 400 may receive the result value attributable to the upper electric field and the result value attributable to the lower electric field, store them as data, and calculate information on the residual charge on the basis of the data. Specifically, the control unit 400 may include a data storage unit and a calculation unit.

In some implementations, the control unit 400 may include the data storage unit which stores data on the result value attributable to the upper electric field and the result value attributable to the lower electric field. The data storage unit may store each of a plurality of result values relative to the upper electric field and a plurality of result values relative to the lower electric field which the upper inspection unit 200 and the lower inspection unit 300 have measured while moving in the horizontal and vertical directions, i.e., the measurement values, as data.

In some implementations, the control unit 400 may include the calculation unit for extracting a result value relative to the upper electric field and a result value relative to the lower electric field. Specifically, the calculation unit may execute an algorithm for extending and calculating values from the result values. The calculation unit may increase the accuracy of the result value relative to the upper electric field and the result value relative to the lower electric field through the algorithm.

Specifically, the algorithm may be for extracting sensing values related to a sensed result value relative to the upper electric field and a result value relative to a sensed result value relative to the lower electric field when the measurement times are the same. For example, the algorithm may be used to extract two values when the upper inspection unit 200 and the lower inspection unit 300 at predetermined intervals apart from the semiconductor substrate 20 sense the result value relative to the upper electric field and the result value relative to the lower electric field, respectively.

The control unit 400 may extract each of the result value relative to the upper electric field and the result value relative to the lower electric field through the algorithm. Specifically, the control unit 400 may be a unit which calculates a true value from the result values relative to the upper electric field and the lower electric field. The control unit 400 may extract each of the result value relative to the upper electric field and the result value relative to the lower electric field on the basis of the association relationship between the result value relative to the upper electric field and the result value relative to the lower electric field through the algorithm.

The calculation unit may extract the result value relative to the lower electric field on the basis of the result value relative to the upper electric field. The calculation unit may extract the result value relative to the upper electric field on the basis of the result value relative to the lower electric field. The extracted result value Qᵤ relative to the upper electric field may be defined by the following Expression 2-1, and the extracted result value Qₗ relative to the lower electric field may be defined by the following Expression 2-2.

$${Q}_{u} = {K}_{1} {Q}_{1} + {K}_{2} {Q}_{2} \qquad Expression 2 - 1$$

$${Q}_{1} = {K}_{2} {Q}_{1} + {K}_{1} {Q}_{2} \qquad Expression 2 - 2$$

(Here, Qᵤ may be the extracted result value relative to the upper electric field, Qₗ may be the extracted result value relative to the lower electric field, Q₁ may be the result value relative to the upper electric field measured by the upper charge sensor, Q₂ may be the result value relative to the lower electric field measured by the lower charge sensor, and K₁ and K₂ may be constant numbers. The sum of K₁ and K₂ may be 1.)

The result value relative to the upper electric field and the result value relative to the lower electric field may be extracted by the above-mentioned simultaneous equations 2-1 and 2-2. However, the present disclosure is not limited thereto, and for example, the result value relative to the upper electric field and the result value relative to the lower electric field may be calculated by a nonlinear expression or an expression reflecting result values measured at different distances multiple times.

The calculation unit may extract the result value relative to the upper electric field on the basis of the influence relationship between the first center region CR1 and the first dummy region DR1 through the algorithm. When the upper probe 210 moves on the upper surface 22 of the semiconductor substrate 20, the upper charge formed on the first center region CR1 and the upper charge formed on the first dummy region DR1 may affect each other. The calculation unit may extract the result value relative to the upper electric field in view of the influence relationship between the first center region CR1 and the first dummy region DR1 through a distribution similar to a Gaussian distribution.

The calculation unit may extract the result value relative to the lower electric field in view of the influence relationship between the second center region CR2 and the second dummy region DR2 through the distribution.

In some implementations, the substrate inspection apparatus 10 may further include a substrate driver 500 which moves the substrate support unit 100. The substrate driver 500 may move the substrate support unit 100, which supports the semiconductor substrate 20, in the horizontal direction. The substrate driver 500 may move the semiconductor substrate 20 between the upper inspection unit 200 and the lower inspection unit 300 through the substrate support unit 100. The substrate driver 500 may move the substrate support unit 100 in a first horizontal direction and a second horizontal direction orthogonal to the first horizontal direction.

In some implementations, the substrate inspection apparatus 10 may be an apparatus which extracts information on the residual charge by deriving a relational expression relative to the result value relative to the upper electric field and the result value relative to the lower electric field from the plurality of measurement values. Specifically, the substrate inspection apparatus 10 may extract information on the residual charge through a ratio related to coefficients of the derived relational expression. In this way, information according to presence of residual internal charge IC as well as the upper and lower surface charge LC may be extracted.

In some implementations, the relational expression related to the result value relative to the upper electric field and the result value relative to the lower electric field may be derived as the following Expression (3).

$$P = ( \begin{matrix}{a}_{11} & {b}_{11} & {c}_{11} \\ {a}_{12} & {b}_{12} & {c}_{12}\end{matrix} ) ( \begin{matrix}Qu \\ Ql \\ Qc\end{matrix} ) \qquad Expression ( 3 )$$

(In Expression 3, P may be the result value relative to the residual charge of the semiconductor substrate 20, Qᵤ may be the result value relative to the electric field attributable to the upper charge remaining at the upper portion of the semiconductor substrate 20, Q may be the result value relative to the electric field attributable to the lower charge remaining at the lower portion of the semiconductor substrate 20, Q_{c} may be the result value relative to the electric field attributable to the charge remaining inside the substrate, and a₁₁, a₁₂, b₁₁, b₁₂, c₁₁, and c₁₂ may be constant numbers).

On the basis of the result values measured by the upper inspection unit 200 and the lower inspection unit 300, the value of the above Expression (3) may be derived. Specifically, a P value according to the above Expression (3) may be derived when the upper inspection unit 200 and the lower inspection unit 300 are spaced apart from the semiconductor substrate 20 in the vertical direction. Thereafter, the upper inspection unit 200 and the lower inspection unit 300 may be disposed at different positions, and then a P value according to the above Expression (3) may be additionally derived. After a plurality of relational expressions of Expression (3) related to P is derived as described above, Qᵤ, Qₗ, and Q_{c} values may be calculated through the relational expressions, whereby information on the surface and internal charge of the semiconductor substrate 20 may be derived.

Specifically, by deriving a point having the same correlation with respect to the plurality of relational expressions, a true value for each factor may be derived. For example, a relational expression of the above Expression (3) may be derived at least three times, and Qᵤ, Qₗ, and Q_{c} may be calculated using the plurality of relational expressions at various positions having the same correlation, whereby information on the surface and internal charge of the semiconductor substrate 20 according to the depth of the semiconductor substrate 20 may be checked out.

However, the present disclosure is not limited thereto, and for example, the result value relative to the upper electric field and the result value relative to the lower electric field may be calculated using a nonlinear expression or various expressions capable of checking the depth of the semiconductor device and the amount of internal charge of the semiconductor substrate by result values measured multiple times.

While repeating the above-described measuring method a plurality of number of times, the upper inspection unit 200 and the lower inspection unit 300 may transmit information on the result value relative to the upper electric field and the result value relative to the lower electric field to the control unit 400. The information transmitted to the control unit 400 may be stored as data, and information on the residual charge remaining on the upper surface 22 and lower surface 24 of the semiconductor substrate 20 and inside the semiconductor substrate may be extracted on the basis of the plurality of stored data items.

For example, a plurality of data items related to a plurality of measurement values may be secured by moving the upper inspection unit 200 and the lower inspection unit 300 only in the vertical direction with respect to the same horizontal axis, and information on the charge in the depth direction of the semiconductor substrate 20 as well as the surface charge of the upper surface 22 and lower surface 24 of the semiconductor substrate 20 may be extracted on the basis of the data items, whereby information on the residual charge, such as the magnitude and distribution of charge, may be checked out.

In some implementations, the substrate inspection apparatus 10 may include an inspection-unit moving unit which moves the upper inspection unit 200 and the lower inspection unit 300. The inspection-unit moving unit may move the upper probe 210 and the lower probe 310, provided with the semiconductor substrate 20 interposed therebetween, in the horizontal and vertical directions to measure information on the residual charge of the semiconductor substrate 20.

When the inspection-unit moving unit moves the upper probe 210 and the lower probe 310 in the horizontal and vertical directions, the substrate support unit 100 which fixes the semiconductor substrate 20 may be fixed at a preset position. The inspection-unit moving unit may move the upper probe 210 and the lower probe 310 in the horizontal and vertical directions with respect to the fixed semiconductor substrate 20. The upper inspection unit 200 and the lower inspection unit 300 may be moved in the horizontal and vertical directions by the inspection-unit moving unit, and measure the upper surface charge and the lower surface charge from the semiconductor substrate 20.

More specifically, the inspection-unit moving unit may move the upper inspection unit 200 and the lower inspection unit 300 in a first direction D₁ which is a horizontal direction along an X axis, and in a second direction D2 which is a vertical direction along a Y axis.

Specifically, the inspection-unit moving unit may drive the upper inspection unit 200 and the lower inspection unit 300 so as to be spaced apart from the semiconductor substrate 20 by a predetermined distance. For example, the inspection-unit moving unit may measure the result value relative to the upper electric field and the result value relative to the lower electric field after separating the upper inspection unit 200 and the lower inspection unit 300 by a predetermined distance, and measure the result value relative to the upper electric field and the result value relative to the lower electric field after moving the upper inspection unit 200 and the lower inspection unit 300 so as to have a separation distance different from the predetermined distance.

When the substrate driver 500 moves the substrate support unit 100 in the horizontal direction, the upper probe 210 and the lower probe 310 may be fixed at preset positions. The substrate driver 500 may move the semiconductor substrate 20 in the horizontal direction between the upper probe 210 and the lower probe 310 fixed, by the substrate support unit 100. The upper inspection unit 200 and the lower inspection unit 300 may measure the result value relative to the upper electric field and the result value relative to the lower electric field derived from the semiconductor substrate 20, which is moved in the horizontal direction by the substrate driver 500, by the surface charge and the residual charge remaining inside.

In some implementations, the substrate inspection apparatus 10 may extract information on the residual charge of the semiconductor substrate 20 from the plurality of measurement values measured by the upper inspection unit 200 and the lower inspection unit 300. Specifically, the substrate inspection apparatus 10 may be an apparatus which extracts information on the residual charge on the upper surface and lower surface of the semiconductor substrate 20 and the residual charge remaining inside the semiconductor substrate from the plurality of measurement values related to the result value relative to the upper electric field and the result value relative to the lower electric field, which the upper inspection unit 200 and the lower inspection unit 300 have measured while moving in the vertical direction. More specifically, the substrate inspection apparatus 10 may measure the surface charge value by the upper inspection unit 200 and the lower inspection unit 300 while changing the heights of the upper inspection unit and the lower inspection unit in the vertical direction, and extract information on the residual charge from the plurality of measurement values measured at the individual positions.

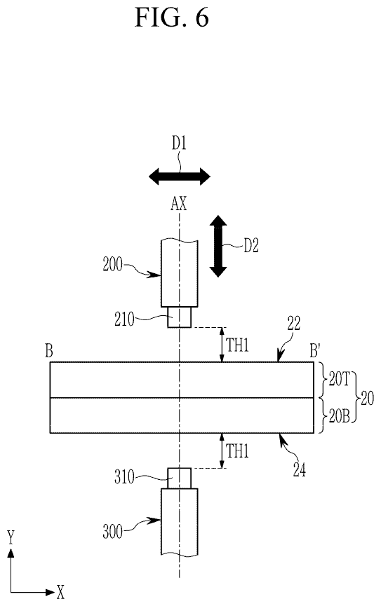

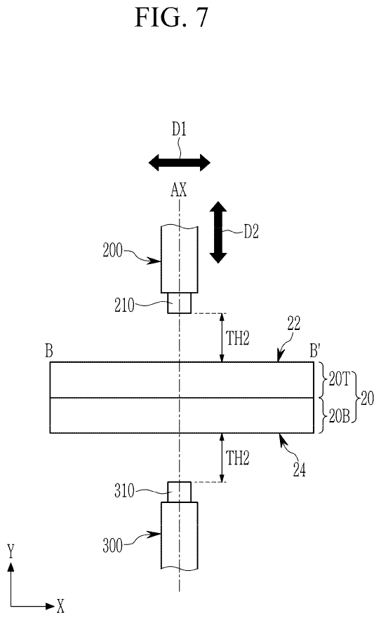

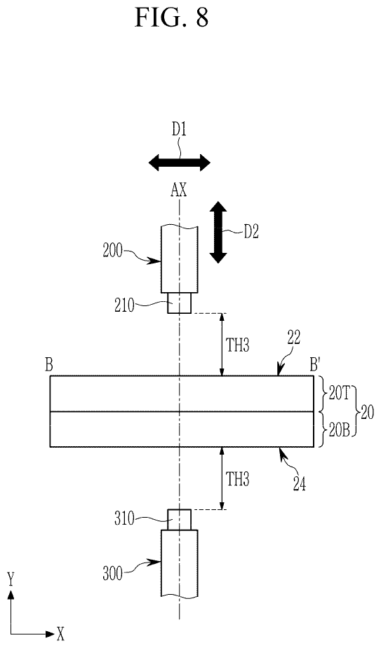

FIGS. 6, 7, and 8 are schematic views illustrating an example of an operation of the substrate inspection apparatus.

Referring to FIGS. 6 to 8, in some implementations, the substrate inspection apparatus 10 may measure information on the semiconductor substrate 20 or information on the residual charge by height varying inspection. Specifically, the upper inspection unit 200 and the lower inspection unit 300 may be units which measures the result value relative to the upper electric field and the result value relative to the lower electric field with respect to the semiconductor substrate 20 by the height varying inspection.

The height varying inspection may be measuring the result values relative to the upper surface charge and the lower surface charge while changing the separation distances of the upper inspection unit 200 and the lower inspection unit 300 from the semiconductor substrate 20. Specifically, the separation distance of the upper inspection unit 200 refers to the separation distance from the upper surface 22 of the semiconductor substrate 20, and the separation distance of the lower inspection unit 300 refers to the separation distance from the lower surface 24 of the semiconductor substrate 20.

For example, the height varying inspection may measure each result value relative to the upper electric field and each result value relative to the lower electric field while changing the separation distances of the upper inspection unit 200 and the lower inspection unit 300 from the semiconductor substrate 20. A relational expression may be derived from the surface charge values, and the values of factors when the coefficients of the relational expression maintain a predetermined ratio may be extracted, whereby information on the residual charge such as the distribution and magnitude of the residual charge remaining inside the semiconductor substrate 20 may be extracted.

In some implementations, the separation distances of the upper inspection unit 200 and the lower inspection unit 300 from the semiconductor substrate 20 may be the same, and the upper inspection unit 200 and the lower inspection unit 300 may measure the result value relative to the upper electric field and the result value relative to the lower electric field while changing the separation distances a plurality of number of times. While the separation distances of the upper inspection unit and the lower inspection unit are maintained equal to each other, the result value relative to the upper electric field and the result value relative to the lower electric field may be measured at different separation distances a plurality of number of times, whereby the accuracy of the measurement values may be improved and information on the charge may be measured.

The upper inspection unit 200 and the lower inspection unit 300 may measure the result values relative to the upper electric field and the result values relative to the lower electric field while increasing the separation distance from the semiconductor substrate 20 in the order of the separation distances TH1, TH2, and TH3 of FIGS. 6, 7, and 8. The separation distances TH1, TH2, and TH3 of FIGS. 6, 7, and 8 may be referred to as a first separation distance TH1, a second separation distance TH2, and a third separation distance TH3, respectively. The above-mentioned separation distances may be adjusted by the inspection-unit moving unit described above with reference to FIGS. 1 to 5.

Specifically, the separation distances may be adjusted by the inspection-unit moving unit, or may be finely adjusted by the upper vertical driver 240 and the lower vertical driver 340. For example, the separation distances may include all of the separation distances of the semiconductor substrate 20 from the first tip 212 and the second tip 312, the upper and lower separation distances UL and LL, the intermediate values between the separation distances between the tips 212 and 312 and the semiconductor substrate 20 and the upper and lower separation distances UL and LL, or distances set by a specific expression, and may be set to specific values depending on the process and the design.

Specifically, after the upper inspection unit 200 and the lower inspection unit 300 are disposed at the first separation distance TH1 and the result value relative to the upper electric field and the result value relative to the lower electric field are measured, a relational expression like Expression (3) may be derived from them. Thereafter, after the upper inspection unit 200 and the lower inspection unit 300 are disposed at the second separation distance TH2 longer than the first separation distance TH1 and the result value relative to the upper electric field and the result value relative to the lower electric field are measured, a relational expression may be derived from them.

Then, after the upper inspection unit 200 and the lower inspection unit 300 are disposed at the third separation distance TH3 longer than the second separation distance TH2 and the result value relative to the upper electric field and the result value relative to the lower electric field are measured, a relational expression may be derived from them. Although three measurements are shown in FIGS. 6 to 8, this is a nonrestrictive example, and it is clear that every case where the correlations of the coefficients of the relational expressions related to the charge values derived depending on different separation distances are the same may be included and the accuracy can be improved through the plurality of measurement processes.

As described above, from the plurality of relational expressions which is derived depending on the separation distances TH1, TH2, and TH3 by the upper inspection unit 200 and the lower inspection unit 300 and are the same in the correlations of the coefficients of the relational expressions, information on the upper portion thickness and lower portion thickness of the semiconductor substrate 20 and the charge remaining inside the semiconductor substrate 20 may be derived.

In some implementations, the upper inspection unit 200 and the lower inspection unit 300 may be provided on the same axis AX. Specifically, the upper inspection unit 200 and the lower inspection unit 300 may be units which move vertically with respect to the same axis AX. More specifically, the upper inspection unit 200 and the lower inspection unit 300 disposed on the same axis AX may measure the result value relative to the upper electric field and the result value relative to the lower electric field while moving vertically in the second direction D2 along a Y axis.

In some implementations, the lower probe 310 may be provided together with the upper probe 210 on the same axis AX. Since the lower probe 310 and the upper probe 210 are provided on the same axis AX, the upper charge sensor 220 and the lower charge sensor 320 may simultaneously measure the result value relative to the upper electric field and the result value relative to the lower electric field from the upper surface 22 and lower surface 24 of the semiconductor substrate 20. Since the lower probe 310 and the upper probe 210 are provided on the same axis AX, the substrate inspection apparatus 10 may determine the influence relationship between the result value relative to the upper electric field and the result value relative to the lower electric field through the upper charge sensor 220 and the lower charge sensor 320.

As described above, referring to FIGS. 6 to 8, the upper inspection unit 200 and the lower inspection unit 300 may be provided on the same axis AX and are positioned so as to have each of the same separation distances TH1, TH2, and TH3, and individual relational expressions may be derived, and from them, the thickness (or depth) of the semiconductor substrate 20 or information on the residual charge such as the magnitude and distribution of the residual charge remaining inside the semiconductor substrate 20 may be derived. The information on the residual charge may be defined as the information on the residual charge on the same axis AX, and transferred to and stored in the control unit 400. Thereafter, the upper inspection unit 200 and the lower inspection unit 300 may move horizontally in the first direction D₁ along the X axis, and the above-mentioned height varying inspection may be performed.

This is a nonrestrictive example, and the separation distances may be adjusted besides the above-described separation distances TH1, TH2, and TH3 such that measurements are performed at various positions as long as the correlations of the coefficients of relational expressions are the same.

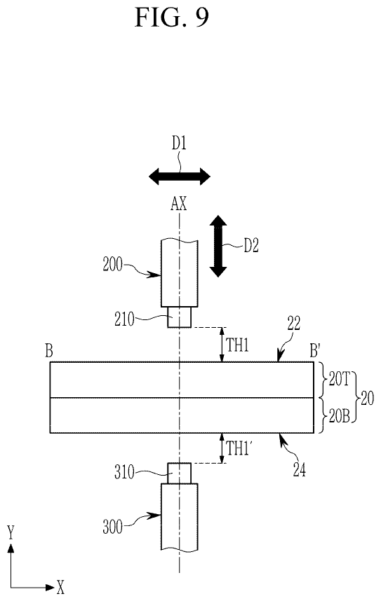

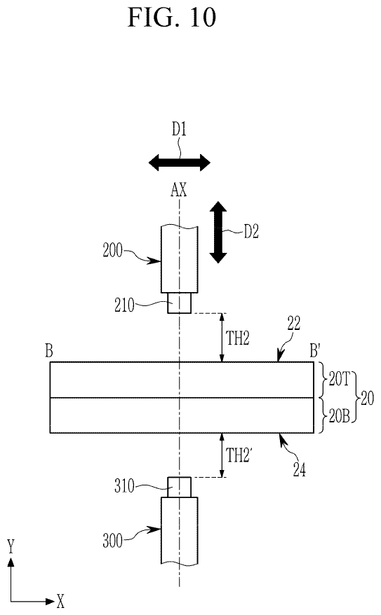

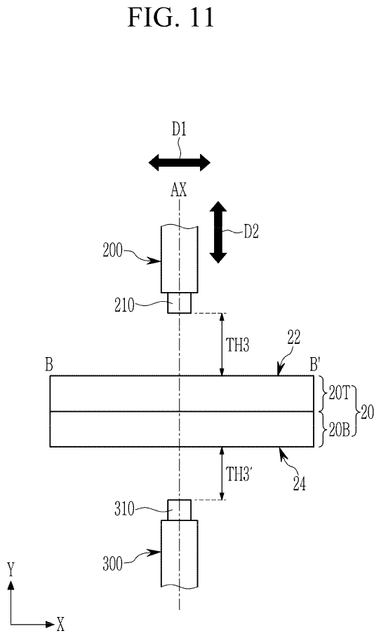

FIGS. 9, 10, and 11 are schematic views illustrating an example of an operation of a substrate inspection apparatus.

Referring to FIGS. 9 to 11, in some implementations, the upper inspection unit 200 and the lower inspection unit 300 may have different separation distances from the semiconductor substrate 20, and the upper inspection unit 200 and the lower inspection unit 300 may be units which measure the result value relative to the upper electric field and the result value relative to the lower electric field while changing the separation distances a plurality of number of times. Not only in the case where the separation distances are maintained equal to each other, but also in the case where the charge values are measured while different distances are maintained, as long as the correlations of relational expressions are the same, information on the charge may be extracted in more various ranges.

The upper inspection unit 200 and the lower inspection unit 300 may measure the result values relative to the upper electric field and the result values relative to the lower electric field while increasing the separation distances from the semiconductor substrate 20 in the order of the separation distances TH1 and TH1′, TH2 and TH2′, and TH3 and TH3′ of FIGS. 9, 10, and 11. The separation distances TH1 and TH1′, TH2 and TH2′, and TH3 and TH3′ of FIGS. 9, 10, and 11 may be referred to as first separation distances TH1 and TH1′, second separation distances TH2 and TH2′, and third separation distances TH3 and TH3′, respectively.

Specifically, after the upper inspection unit 200 and the lower inspection unit 300 may be disposed at the first separation distances TH1 and TH1′ as shown in FIG. 9, and the result value relative to the upper electric field and the result value relative to the lower electric field are measured, a relational expression like Expression (3) may be derived from them. Thereafter, after the upper inspection unit 200 and the lower inspection unit 300 are disposed at the second separation distances TH2 and TH2′ longer than the first separation distances TH1 and TH1′ and the result value relative to the upper electric field and the result value relative to the lower electric field are measured, a relational expression may be derived from them.

Then, after the upper inspection unit 200 and the lower inspection unit 300 are disposed at the third separation distances TH3 and TH3′ longer than the second separation distances TH2 and TH2′ and the result value relative to the upper electric field and the result value relative to the lower electric field are measured, a relational expression may be derived from them. Although three measurements are shown in FIGS. 9 to 11, this is a nonrestrictive example, and it is clear that every case where the correlations of the coefficients of the relational expressions related to the charge values derived depending on different separation distances are the same may be included and the accuracy can be improved through the plurality of measurement processes.

In some implementations, the length may increase equally in the order of the first separation distances TH1 and TH1′, the second separation distances TH2 and TH2′, and the third separation distances TH3 and TH3′. In some implementations, the length may increase differently in the order of the first separation distances TH1 and TH1′, the second separation distances TH2 and TH2′, and the third separation distances TH3 and TH3′. As described above, the increase or decrease rates of the lengths of the first separation distances TH1 and TH1′, the second separation distances TH2 and TH2′, and the third separation distances TH3 and TH3′ may be the same or different, and all may be included as long as the correlations of the coefficients of relational expressions are maintained the same.

As described above, referring to FIGS. 9 to 11, the upper inspection unit 200 and the lower inspection unit 300 may be positioned so as to have each of the pairs of different separation distances TH1 and TH1′, TH2 and TH2′, and TH3 and TH3′, and individual relational expressions may be derived, and from them, the thickness (or depth) of the semiconductor substrate 20 or information on the residual charge such as the magnitude and distribution of the residual charge remaining inside the semiconductor substrate 20 may be derived.

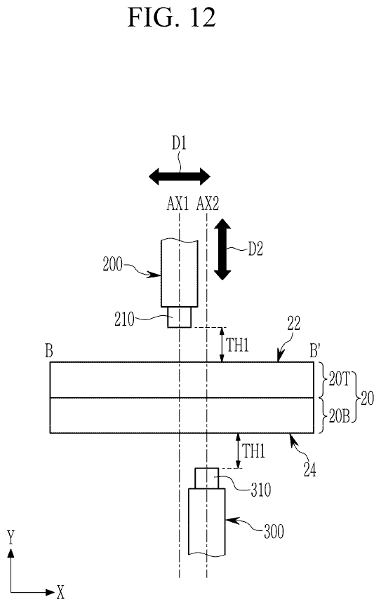

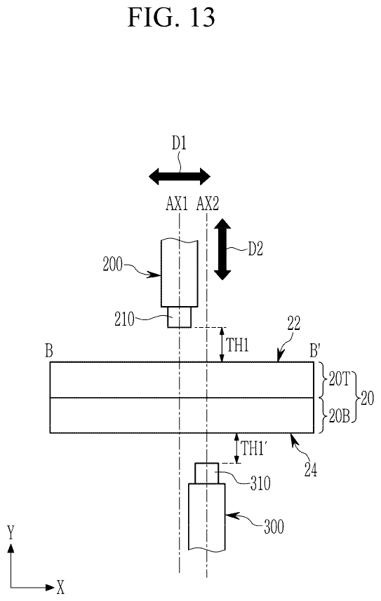

FIGS. 12 and 13 are views illustrating an example of an operation of a substrate inspection apparatus.

Referring to FIGS. 12 and 13, in some implementations, the upper inspection unit 200 may be provided on a first axis AX1 which is a vertical direction, and the lower inspection unit 300 may be provided on a second axis AX2 which is a vertical direction. Specifically, the upper inspection unit 200 and the lower inspection unit 300 may be units which vertically move in a state where they are disposed on the first axis AX1 and the second axis AX2 different from each other and positioned so as to be spaced apart in the horizontal direction, respectively. More specifically, the upper inspection unit 200 and the lower inspection unit 300 disposed on the first axis AX1 and the second axis AX2 may measure the result value relative to the upper electric field and the result value relative to the lower electric field while moving vertically in the second direction D2 along the Y axis.

Referring to FIG. 12 again, in some implementations, the upper inspection unit 200 and the lower inspection unit 300 provided on the different axes AX1 and AX2 may have the same separation distance TH1 from the semiconductor substrate 20. When the surface charge values are measured at the same separation distance TH1, since the possibility that it is a point where the correlations of the coefficients of relational expressions which are derived are the same is high, information on the semiconductor substrate 20 or information on the charge remaining inside the semiconductor substrate 20 can be quickly and accurately secured.

Referring to FIG. 13 again, in some implementations, the upper inspection unit 200 and the lower inspection unit 300 provided on the different axes AX1 and AX2 may have the different separation distances TH1 and TH1′ from the semiconductor substrate 20. Even if the surface charge values are measured in the state where the separation distances TH1 and TH1′ are different, a plurality of relational expressions between points where the correlations of the coefficients of relational expressions which are derived are the same may be extracted, whereby information on the semiconductor substrate 20 or information on the charge remaining inside the semiconductor substrate 20 can be secured.

As described above, referring to FIGS. 12 and 13, the upper inspection unit 200 and the lower inspection unit 300 may be positioned on the different axes AX1 and AX2, and the result values relative to the upper and lower electric fields may be measured while the upper inspection unit 200 and the lower inspection unit 300 are moved in the D2 direction which is the Y axis direction, and from them, individual relational expressions may be derived, and through the derived relational expressions, the thickness (or depth) of the semiconductor substrate 20 or information on the residual charge such as the magnitude and distribution of the residual charge remaining inside the semiconductor substrate 20 may be derived. The information on the thickness of the semiconductor substrate 20 and the information the residual charge may be values derived on the basis of the region between the first axis AX1 and the second axis AX2.

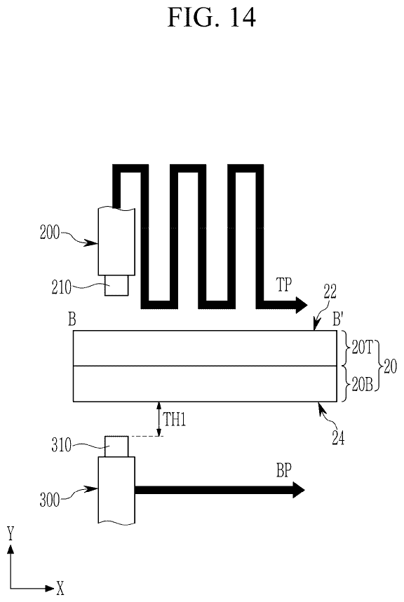

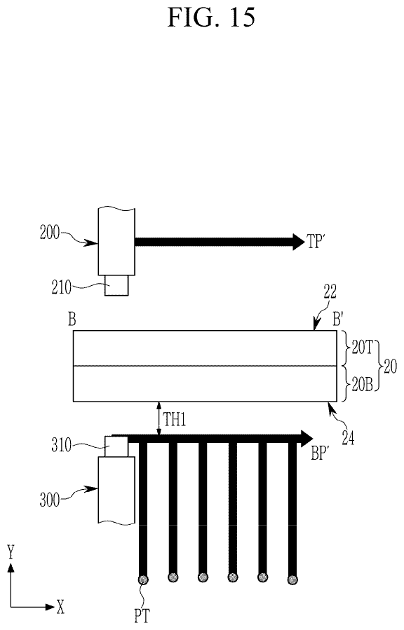

FIGS. 14 and 15 are schematic views illustrating an example of an operation of a substrate inspection apparatus.

Referring to FIGS. 14 and 15, in some implementations, one of the upper inspection unit 200 and the lower inspection unit 300 may be disposed at a fixed position. Specifically, one of the upper inspection unit 200 and the lower inspection unit 300 which move vertically may move only in the horizontal direction in the state where it is fixed.

More specifically, as shown in FIG. 14, the lower inspection unit 300 which does not move in the vertical direction may move in the horizontal direction which is the X axis direction along a lower path BP while maintaining the same separation distance TH1 from the lower surface 24 of the semiconductor substrate 20. As shown in FIG. 15, the upper inspection unit 200 which does not move in the vertical direction may move in the horizontal direction which is the X axis direction along an upper path TP′ while maintaining the same separation distance from the upper surface 22 of the semiconductor substrate 20.

Alternatively, one of the upper inspection unit 200 and the lower inspection unit 300 which moves in the vertical direction may measure the result value relative to the electric field while moving in the vertical direction to a predetermined height, moving in the horizontal direction, and then moving in the vertical direction to the predetermined height again. Specifically, although it is shown in FIG. 14 that the upper inspection unit 200 moves in the vertical direction, and it is shown in FIG. 15 that the lower inspection unit 300 moves in the vertical direction, these are nonrestrictive examples, and each may include the reversed case.

Referring to FIG. 14 again, the upper inspection unit 200 may be spaced apart from the semiconductor substrate 20, and measure the result value relative to the upper electric field while moving in the vertical direction. Specifically, the upper inspection unit 200 may measure the result value relative to the upper electric field while moving in the Y axis direction to a predetermined height, and then move in the horizontal direction by a predetermined distance, and measure the result value relative to the upper electric field while moving vertically toward the semiconductor substrate 20 along the Y axis. More specifically, the upper inspection unit 200 may measure the upper surface charge remaining on the upper surface 22 of the semiconductor substrate 20 while moving horizontally and vertically along an upper path TP.

The lower inspection unit 300 may move in the horizontal direction along the lower path BP while maintaining the separation distance TH1 from the semiconductor substrate 20. Specifically, the lower inspection unit 300 may move along the lower path BP so as to correspond to the Y axis positioned on the upper inspection unit 200.

The lower inspection unit 300 may move so as to correspond to the Y axis direction to form an electric field with the upper inspection unit 200. Specifically, the lower inspection unit 300 and the upper inspection unit 200 may form an electric field, and the lower inspection unit 300 may move so as to correspond to the upper inspection unit 200 to obtain information on the semiconductor substrate 20 and information on the residual charge inside the semiconductor substrate 20.

In some implementations, the upper inspection unit 200 and the lower inspection unit 300 may be units which move along the same axis. As the upper inspection unit 200 and the lower inspection unit 300 move along the same axis, the above-mentioned information on the semiconductor substrate 20 and the residual charge can be obtained more accurately and simply.

In some implementations, the upper inspection unit 200 and the lower inspection unit 300 may be units which move along different axes. Even if the upper inspection unit 200 and the lower inspection unit 300 move along different axes, information on the residual charge can be obtained in a wider range as long as the upper inspection unit 200 and the lower inspection unit 300 are disposed at positions sufficient to form an electric field.

Referring to FIG. 15 again, in some implementations, the upper inspection unit 200 may move in the horizontal direction along the upper path TP′ while maintaining a predetermined separation distance from the semiconductor substrate 20. Specifically, the upper inspection unit 200 may move along the upper path TP′ so as to correspond to the Y axis of the lower inspection unit 300.

The lower inspection unit 300 may be spaced apart from the semiconductor substrate 20, and measure the result value relative to the lower electric field while moving in the vertical direction. Specifically, the lower inspection unit 300 may measure the result value relative to the lower electric field while moving in the Y axis direction to a specific height PT, and measure the result value relative to the lower electric field while repeating the process of moving to the initial position, moving in the horizontal direction by a predetermined distance, and then moving in the Y axis direction to the specific height PT. In this case, the result value relative to the lower electric field may be measured only when the lower inspection unit 300 moves in the Y axis direction to the specific height PT, and may also be measured even when the lower inspection unit moves to the initial position. As described above, the lower inspection unit 300 may be a unit which moves along a lower path BP′. This is a nonrestrictive example, and the opposite case thereto may also be included.

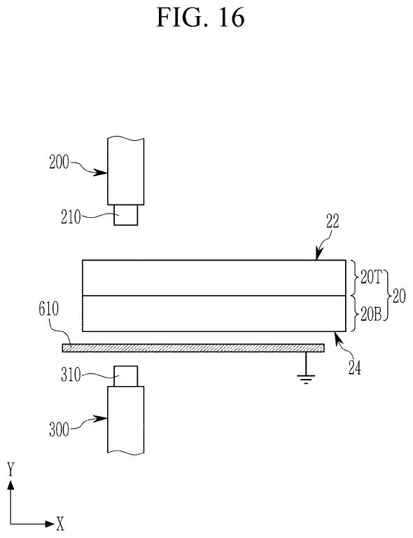

FIGS. 16, 17, and 18 are views illustrating an example of an operation of a substrate inspection apparatus.

Referring to FIG. 16, in some implementations, the substrate inspection apparatus 10 may further include a dummy probe 610. The dummy probe 610 may be a probe which is disposed so as to correspond to the upper inspection unit 200 or the lower inspection unit 300 and forms an electric field for measuring the residual charge inside the semiconductor substrate 20.

The dummy probe 610 may be a ground structure. Specifically, the dummy probe 610 may be a structure grounded from the ground. When the dummy probe 610 is included in the substrate inspection apparatus 10, the surface charge value may be measured while only one of the upper inspection unit 200 and the lower inspection unit 300 is moved.

In some implementations, the dummy probe 610 may be disposed either between the semiconductor substrate 20 and the upper inspection unit 200 or between the semiconductor substrate 20 and the lower inspection unit 300. Specifically, the dummy probe 610 may be disposed in a first region which is a predetermined region between the semiconductor substrate 20 and the upper inspection unit 200, or may be disposed in a second region which a predetermined region between the semiconductor substrate 20 and the lower inspection unit 300. For example, the first region refers to the separation space between the upper surface 22 and the upper inspection unit 200, and the second region refers to the separation space between the lower surface 24 and the lower inspection unit 300.

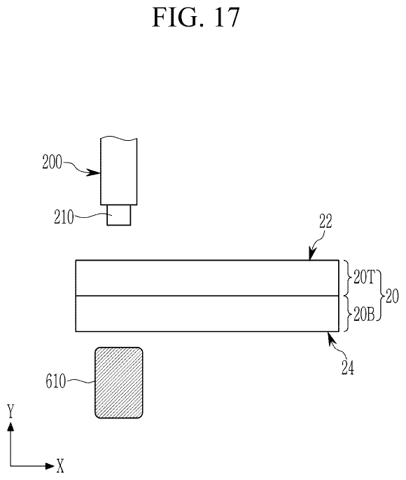

Referring to FIGS. 16 and 17, in some implementations, the dummy probe 610 may have a plate or rod shape. The dummy probe 610 may be a member for forming an electric field with the upper inspection unit 200 or the lower inspection unit 300, and may contain a metal material. This is a nonrestrictive example, and the dummy probe 610 may be a ground structure, and may be made of various materials in various shapes as long as it can form an electric field with the upper inspection unit 200 or the lower inspection unit 300 and minimize interference when measuring and extracting the result value relative to the electric field of the upper inspection unit 200 or the lower inspection unit 300.

In some implementations, a dummy probe 610 having a plate shape may be disposed on the semiconductor substrate 20. Specifically, the dummy probe 610 may be a ground structure, and may be disposed so as to be in contact with the semiconductor substrate 20 or may be disposed so as to be spaced apart from the semiconductor substrate by a predetermined distance.

In some implementations, a dummy probe 610 having a rod shape may be installed so as to be movable in the horizontal direction on the lower surface 24 of the semiconductor substrate 20. When the upper inspection unit 200 moves in a horizontal direction, the dummy probe 610 may move in the X axis direction which is a horizontal direction so as to correspond thereto.

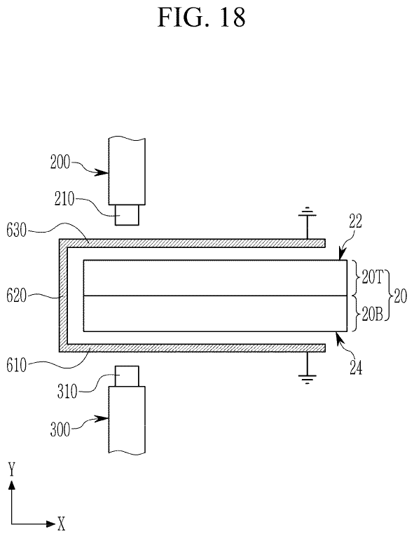

Referring to FIG. 18 again, in some implementations, the substrate inspection apparatus 10 may further include a dummy probe driver 630. The dummy probe driver 630 may move the dummy probe in the horizontal direction. Specifically, the dummy probe driver 630 may drive a lower dummy probe 610 which is disposed in the first region between the lower inspection unit 300 and the semiconductor substrate 20, and an upper dummy probe 620 which is disposed in the second region between the upper inspection unit 200 and the semiconductor substrate 20, in the horizontal direction.

The dummy probe driver 630 may be connected to the lower dummy probe 610 and the upper dummy probe 620 and driven. Specifically, the dummy probe driver 630 may be controlled so as to serve as a ground structure when the upper inspection unit 200 or the lower inspection unit 300 measures the result value relative to the electric field while moving in the vertical direction. For example, the dummy probe driver 630 may dispose the lower dummy probe 610 so as to correspond to the axis of the upper inspection unit 200 when the upper inspection unit 200 measures the result value relative to the upper electric field while moving in the vertical direction, and dispose the upper dummy probe 620 so as to be spaced apart from the axis of the upper inspection unit 200 to minimize interference of the upper inspection unit 200.

In contrast, the dummy probe driver 630 may dispose the upper dummy probe 620 so as to correspond to the vertical axis of the lower inspection unit 300 when the lower inspection unit 300 measures the result value relative to the lower electric field while moving in the vertical direction, and dispose the lower dummy probe 610 so as to be spaced apart from the vertical axis of the lower inspection unit 300 to minimize interference of the lower inspection unit 300. As described above, the dummy probe driver 630 may perform substrate inspection by moving the lower dummy probe 610 and the upper dummy probe 620 depending on the process.

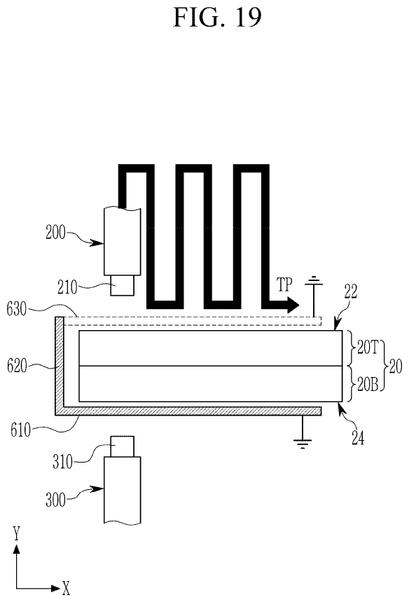

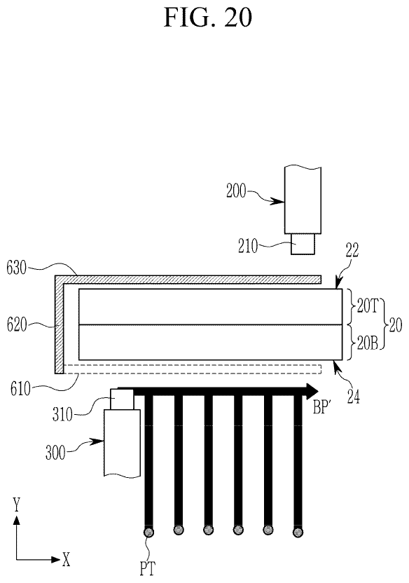

FIGS. 19 and 20 are schematic views illustrating an example of an operation of the substrate inspection apparatus 10 of FIG. 16.

Referring to FIG. 19, in some implementations, the dummy probe driver 630 may move the dummy probe 610 or 620 to one region of the first region between the semiconductor substrate 20 and the lower inspection unit 300 and the second region between the semiconductor substrate 20 and the upper inspection unit 200. Specifically, the dummy probe driver 630 may move the dummy probes 610 and 620 not only in the horizontal direction but also in the vertical direction.

The dummy probe driver 630 may dispose the lower dummy probe 610 in the first region when the upper inspection unit 200 measures the result value relative to the upper electric field while moving in the vertical direction, such that the lower dummy probe 610 corresponds to the vertical axis of the upper inspection unit 200.

In contrast, referring to FIG. 20, when the lower inspection unit 300 measures the result value relative to the lower electric field while moving in the vertical direction, the lower dummy probe 610 may be disposed so as to be spaced apart from the vertical axis, and moved in the vertical direction through the dummy probe driver 630, and then, the upper dummy probe 620 may be disposed in the second region. In this case, the upper dummy probe 620 may be the lower dummy probe 610 moved upward through the dummy probe driver 630. Specifically, unlike in FIG. 18 in which the lower dummy probe 610 and the upper dummy probe 620 are separately and independently disposed, one dummy probe (610 and 620) may be integrated with the dummy probe driver 630, and driven by the dummy probe driver 630 as needed.

As a detailed description of driving of the upper inspection unit 200 and the lower inspection unit 300 in the vertical and horizontal directions and measuring and extracting of a result value relative to an electric field, the above description made with reference to FIGS. 1 to 18 may be referred to within a range in which there is no contradiction.

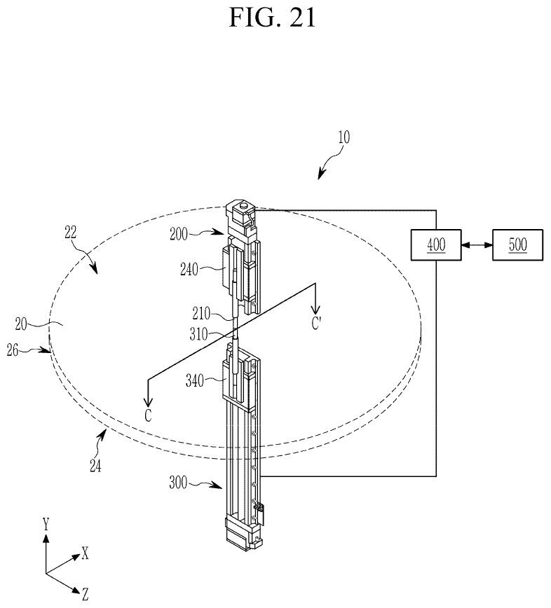

FIG. 21 is a perspective view illustrating an example of the upper inspection unit and lower inspection unit of FIG. 1.

Referring to FIG. 21, a substrate inspection apparatus 10 may include a substrate support unit 100, an upper inspection unit 200, a lower inspection unit 300, a control unit 400, and a simulation data unit 500. Since the contents of the substrate support unit 100, the upper inspection unit 200, the lower inspection unit 300, and the control unit 400 are identical to the above description within a range in which there is no contradiction, the simulation data unit 500 will be described below.

The simulation data unit 500 may secure and store simulation result values related to the residual charge remaining on the upper surface 22 and lower surface 24 of the semiconductor substrate 20 and the residual charge remaining inside the semiconductor substrate on the basis of at least one of the information on the semiconductor substrate 20 and the information on the residual charge, in advance. Specifically, when information on at least one of the information on the thickness (depth) of the semiconductor substrate 20 and the information on the residual charge such as the distribution, magnitude, or amount of the residual charge remaining inside the semiconductor substrate 20 has been secured, the simulation data unit 500 may perform a simulation on the basis of them, and obtain and store the result value thereof.

The simulation data unit 500 may include a software tool for extracting and interpreting simulation data. The software tool is a nonrestrictive example, and a tool such as ANSYS, COMSOL Multiphysics, Abaqus, SimScale, MATLAB Simulink, or Altair HyperWorks may be used.

The simulation data may be data which is extracted by a finite element method (FEM)

The finite element method may be a method of mathematically modeling and interpreting a complex structure or system. The substrate inspection apparatus 10 of the present disclosure may secure simulation data using the software tool on the basis of a numerical analysis method such as the finite element method.

In some implementations, the simulation data unit 500 may be operated in conjunction with the control unit 400. Specifically, the simulation data unit 500 may provide simulation data in conjunction with the calculation unit of the control unit 400.

In some implementations, when some information of the information on the semiconductor substrate 20 or the information on the residual charge has been secured, the simulation data unit 500 may perform a simulation on the basis of them, thereby securing simulation data on the residual charge. Thereafter, the data may be provided to the control unit 400, and a plurality of measurement values measured by the upper inspection unit 200 and the lower inspection unit 300 and the simulation data, stored in the control unit 400, may be compared to each other, and this may be used in a calculation to more accurately secure the information on the residual charge inside the semiconductor substrate 20.

As described above, the substrate inspection apparatus 10 may calculate data on the residual charge from the plurality of measurement values measured by the inspection units and stored in the control unit 400, and use the simulation data, secured in advance and stored in the simulation data unit 500, during the calculation, thereby more accurately deriving the information on the residual charge remaining not only on the surface of the semiconductor substrate 20 but also inside the semiconductor substrate 20.

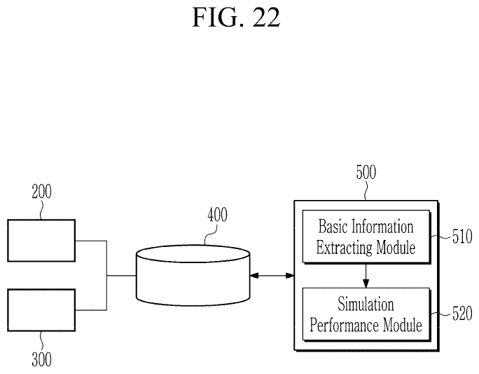

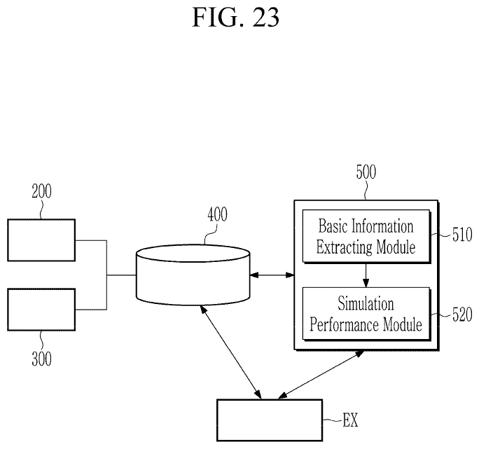

FIGS. 22 and 23 are schematic views illustrating an example of the substrate inspection apparatus 10 of FIG. 21.

Referring to FIG. 22, in some implementations, the simulation data unit 500 may include a basic information extracting module 510 and a simulation performance module 520. Specifically, the basic information extracting module 510 may extract the information on the semiconductor substrate 20 or the information on the residual charge secured in advance. For example, when the information on the thickness of the semiconductor substrate 20 or the residual charge inside the semiconductor substrate 20 is known, the corresponding information may be extracted and stored in the basic information extracting module 510 before a simulation is performed.

The simulation performance module 520 may perform a simulation on the basis of the basic information stored in the basic information extracting module 510, thereby deriving the simulation result value. Specifically, the simulation result value may be a simulation result value of a result value relative to the upper electric field and the lower electric field.

For example, when the information on the thicknesses of the upper substrate 20T and lower substrate 20B in the semiconductor substrate 20 have been secured but the information on the residual charge has not been secured, the information on the semiconductor substrate 20 may be transferred to the basic information extracting module 510, and the simulation performance module 520 may obtain a simulation result value on the basis of the above-mentioned information.

The simulation performance module 520 may perform a simulation on the basis of the basic information obtained by the basic information extracting module 510. For example, the simulation performance module 520 may secure simulation data on the residual charge using a software tool such as ANSYS, COMSOL Multiphysics, Abaqus, SimScale, MATLAB Simulink, or Altair HyperWorks on the basis of the finite element method.

In some implementations, the control unit 400 may be operated in conjunction with the simulation data unit 500. Specifically, the control unit 400 in which the plurality of data items measured by the inspection units has been stored may combine the calculation values calculated by the calculation unit in the control unit 400 and the simulation result value, in conjunction with the simulation data unit 500, thereby more accurately determining the information on the residual charge remaining not only on the surface of the semiconductor substrate 20 but also inside the semiconductor substrate.

As described above, the simulation data obtained by the simulation data unit 500 and the result value relative to the upper electric field and the result value relative to the lower electric field measured by the upper inspection unit 200 and the lower inspection unit 300 and stored in the control unit 400 may be used simultaneously to extract the distribution of the charge remaining on the surface of the semiconductor substrate 20 and inside the semiconductor substrate, such as the magnitude distribution and the position distribution.

Referring to FIG. 23, in some implementations, the substrate inspection apparatus 10 may include an extracting unit EX which extracts and outputs the information on the residual charge, extracted from the control unit 400 and the simulation data unit 500, to a separate member. The extracting unit EX may synthesize and receive the information on the residual charge extracted from the control unit 400 and the simulation data unit 500, in conjunction with the control unit 400 and the simulation data unit 500, and output them.

For example, the extracting unit EX may output the information on the residual charge to a display screen for visual display, or output the information on the residual charge to the outside via a communication interface for transferring the information on the residual charge to a network or another system, such as a USB port, an Ethernet port, or a wireless (Wi-Fi) transmitter.

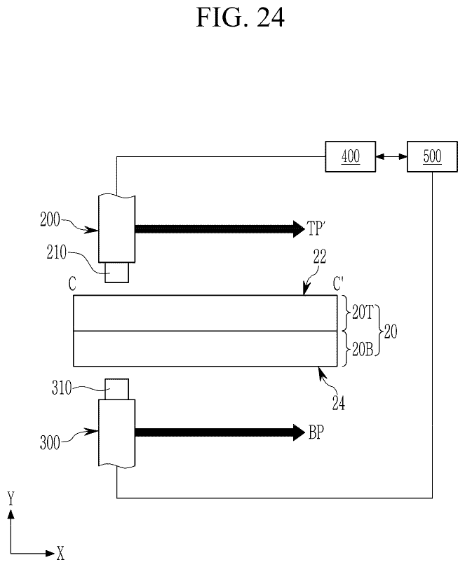

FIGS. 24, 25, and 26 are example schematic cross-sectional views taken along line C-C′ of FIG. 21 and illustrating an example of the operation of the substrate inspection apparatus.

Referring to FIG. 24, the substrate inspection apparatus 10 including the simulation data unit 500 may include the upper inspection unit 200 and the lower inspection unit 300 which measure the result value relative to the upper electric field and the result value relative to the lower electric field while moving in the horizontal direction. The substrate inspection apparatus 10 may include the simulation data unit 500, and the simulation data unit 500 may be operated in conjunction with the control unit 400, whereby more accurate information on the residual charge can be obtained even if the upper inspection unit 200 and the lower inspection unit 300 measure the surface charge values while moving in the horizontal direction without separate vertical movement with respect to the surface charge values.

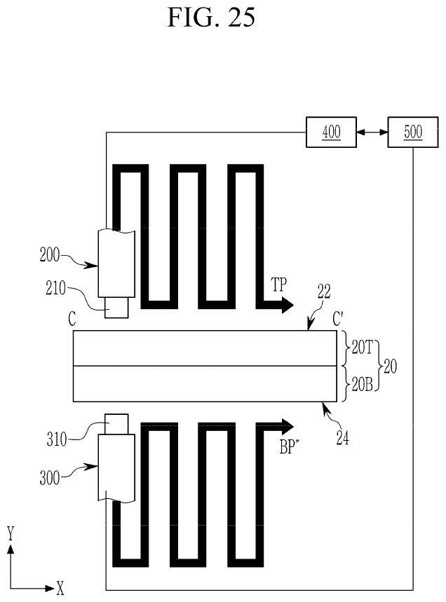

Referring to FIG. 25, the substrate inspection apparatus 10 including the simulation data unit 500 may be able to move at least one of the upper inspection unit 200 and the lower inspection unit 300 in the vertical direction. Specifically, the upper inspection unit 200 and the lower inspection unit 300 may measure the result value relative to the upper electric field and the result value relative to the lower electric field while changing the separation distances from the semiconductor substrate 20. For example, the upper inspection unit 200 may move along the upper path TP, and the lower inspection unit 300 may move along a lower path BP″. On the basis of data on the measurement values of surface charge which the upper inspection unit 200 and the lower inspection unit 300 have measured by the height varying inspection and the data in the simulation data unit 500, more accurate information on the residual charge can be extracted.

In FIGS. 24 and 25, it is shown that the upper inspection unit 200 and the lower inspection unit 300 are driven along the same axis so as to be symmetrical; however, this is a nonrestrictive example, and while the upper inspection unit 200 moves horizontally and the lower inspection unit 300 performs vertical and horizontal movements, they may measure the result value relative to the electric fields. As described above, the upper inspection unit 200 and the lower inspection unit 300 may include every case of sensing a result value relative to an electric field while moving along various upper paths or lower paths as shown in FIGS. 6 to 15 described above.

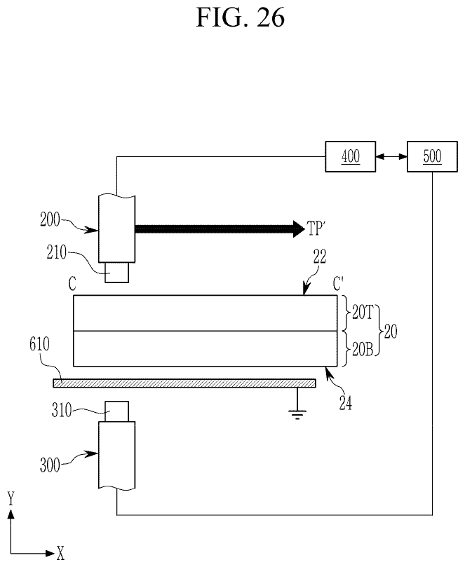

Referring to FIG. 26, the substrate inspection apparatus 10 including the simulation data unit 500 may include the dummy probe 610 which is disposed either between the semiconductor substrate 20 and the upper inspection unit 200 or between the semiconductor substrate 20 and the lower inspection unit 300 and disposed in a direction parallel with the semiconductor substrate 20. The dummy probe 610 may be a ground structure, and include a member which moves only one of the upper inspection unit 200 and the lower inspection unit 300 which are included in the substrate inspection apparatus 10 and assists in measuring a result value relative to an electric field.

In FIG. 26, only the content in which the dummy probe 610 is disposed between the semiconductor substrate 20 and the lower inspection unit 300 is shown; however, as shown in FIGS. 16 to 20 described above, dummy probes 610 of various implementations may be disposed.

The steps constituting the method according to some implementations may be performed in any suitable order unless otherwise indicated herein or otherwise clearly contradicted by context. The present disclosure is not necessarily limited to the described order of the steps.

The use of all examples or exemplary terms in this specification is intended merely to describe the present disclosure in detail, and the scope of the present disclosure is not limited by them. Further, it will be apparent to one of ordinary skill in the art that various modifications, combinations, and changes may be carried out within the scope of the claims or equivalents thereof.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with implementations, it is to be understood that the present disclosure is not limited to the disclosed implementations. On the contrary, it is intended to cover various modifications and equivalent arrangements included within the spirit and scope of the appended claims.

What is claimed is:

1. A substrate inspection apparatus comprising:
a substrate support configured to fix a semiconductor substrate and expose an upper surface and a lower surface of the semiconductor substrate;
an upper inspection circuit configured to obtain a first result value relative to an upper electric field from the upper surface; and
a lower inspection circuit configured to obtain a second result value relative to a lower electric field from the lower surface,
wherein the upper inspection circuit and the lower inspection circuit are configured to measure a plurality of measurement values including the first result value at each of one or more first positions with respect to the semiconductor substrate and the second result value at each of one or more second positions with respect to the semiconductor substrate, and
wherein the substrate inspection apparatus is configured to extract information on residual charge remaining on the upper surface of the semiconductor substrate, on the lower surface of the semiconductor substrate, and inside the semiconductor substrate.

2. The substrate inspection apparatus of claim 1, wherein the substrate inspection apparatus is configured to:
derive, from the plurality of measurement values, one or more relational expressions related to the first result value and the second result value, and
extract, based on the one or more relational expressions, the information on the residual charge.

3. The substrate inspection apparatus of claim 1, comprising:
a data storage circuit configured to receive the plurality of measurement values from the upper inspection circuit and the lower inspection circuit and store the plurality of measurement values; and
a calculation circuit configured to calculate the information on the residual charge based on data received from the data storage circuit.

4. The substrate inspection apparatus of claim 1, comprising:
a simulation data circuit configured to secure simulation data based on substrate information of the semiconductor substrate and the information on the residual charge.

5. The substrate inspection apparatus of claim 4, wherein the simulation data circuit is configured to:
derive the simulation data based on the substrate information and the information on the residual charge, and
wherein the substrate inspection apparatus is configured to extract the information on the residual charge based on comparing the information on the residual charge and the simulation data.

6. The substrate inspection apparatus of claim 4, wherein:
the simulation data circuit is configured to extract the simulation data based on a finite element method.

7. The substrate inspection apparatus of claim 1, wherein the upper inspection circuit is configured to measure the first result value based on changing a first separation distance of the upper inspection circuit from the semiconductor substrate, and
wherein the lower inspection circuit is configured to measure the second result value based on changing a second separation distance of the lower inspection circuit from the semiconductor substrate.

8. The substrate inspection apparatus of claim 7, wherein:
the first separation distance is a same as the second separation distance, and
wherein the upper inspection circuit and the lower inspection circuit are configured to measure the first result value and the second result value based on changing the first separation distance and the second separation distance a plurality of number of times.

9. The substrate inspection apparatus of claim 7, wherein:
the first separation distance is different from the second separation distance, and
wherein the upper inspection circuit and the lower inspection circuit are configured to measure the first result value and the second result value based on changing the first separation distance and the second separation distance a plurality of number of times.

10. The substrate inspection apparatus of claim 1, wherein:
the upper inspection circuit is configured to remain at a fixed position while the lower inspection circuit moves in a vertical direction with respect to the semiconductor substrate and measures the information on the residual charge, or
the lower inspection circuit is configured to remain at a fixed position while the upper inspection circuit moves in the vertical direction with respect to the semiconductor substate and measures the information on the residual charge.

11. The substrate inspection apparatus of claim 1, wherein:
the upper inspection circuit and the lower inspection circuit are configured to move vertically with respect to a same axis.

12. The substrate inspection apparatus of claim 1, wherein:
the upper inspection circuit is configured to move vertically along a first axis that extends in a vertical direction,
the lower inspection circuit is configured to move vertically along a second axis that extends in the vertical direction, and
the first axis and the second axis are spaced apart in a horizontal direction.

13. The substrate inspection apparatus of claim 1, comprising:
a dummy probe that is disposed between the semiconductor substrate and the upper inspection circuit or between the semiconductor substrate and the lower inspection circuit, the dummy probe being disposed in a direction parallel with the semiconductor substrate.

14. The substrate inspection apparatus of claim 13, comprising:
a dummy probe driver that is configured to move the dummy probe to a first region between the semiconductor substrate and the lower inspection circuit or a second region between the semiconductor substrate and the upper inspection circuit.

15. A substrate inspection apparatus comprising:
a substrate support configured to fix a semiconductor substrate and expose an upper surface and a lower surface of the semiconductor substrate;
an upper inspection circuit configured to obtain a first result value relative to an upper electric field from the upper surface;
a lower inspection circuit configured to obtain a second result value relative to a lower electric field from the lower surface;
a control circuit that is configured to receive a plurality of measurement values from the upper inspection circuit and the lower inspection circuit, store the plurality of measurement values as data, and calculate information on residual charge based on the data; and
a simulation data circuit that is configured to secure simulation data based on substrate information of the semiconductor substrate and information on residual charge inside the semiconductor substrate;
wherein the control circuit is configured to extract information on residual charge remaining on the upper surface of the semiconductor substrate, on the lower surface of the semiconductor substrate, and inside the semiconductor substrate based on the first result value, the second result value, and the simulation data.

16. The substrate inspection apparatus of claim 15, wherein:
at least one of the upper inspection circuit and the lower inspection circuit is configured to move in a vertical direction.

17. The substrate inspection apparatus of claim 15, wherein:
the data includes a relational expression related to the first result value and the second result value that are measured based on changing a first separation distance of the upper inspection circuit from the semiconductor substrate and a second separation distance of the lower inspection circuit from the semiconductor substrate,
the simulation data circuit is configured to extract the simulation data based on a finite element method, and
the control circuit is configured to extract the information on the residual charge based on the data and the simulation data.

18. The substrate inspection apparatus of claim 17, wherein:
the first separation distance is a same as the second separation distance.

19. The substrate inspection apparatus of claim 16, wherein:
the upper inspection circuit is configured to remain at a fixed position while the lower inspection circuit moves in the vertical direction with respect to the semiconductor substrate and measures the information on the residual charge, or
the lower inspection circuit is configured to remain at a fixed position while the upper inspection circuit moves in the vertical direction with respect to the semiconductor substrate and measures the information on the residual charge.

20. A substrate inspection apparatus comprising:
a substrate support configured to fix a semiconductor substrate and expose an upper surface and a lower surface of the semiconductor substrate;
an upper inspection circuit that includes an upper probe spaced apart from the upper surface and an upper charge sensor configured to obtain a first result value relative to an upper electric field from the upper surface;
a lower inspection circuit that includes a lower probe spaced apart from the lower surface and a lower charge sensor configured to obtain a second result value relative to a lower electric field from the lower surface;
a control circuit that is configured to receive a plurality of measurement values from the upper inspection circuit and the lower inspection circuit, store the plurality of measurement values as data, and calculate information on residual charge based on the data; and
a simulation data circuit that is configured to secure simulation data based on substrate information of the semiconductor substrate and information on residual charge inside the semiconductor substrate,
wherein at least one of the upper inspection circuit and the lower inspection circuit is configured to be able to be separated in a vertical direction, and
wherein at least one of the upper inspection circuit and the lower inspection circuit is configured to extract information on residual charge remaining on the upper surface of the semiconductor substrate, on the lower surface of the semiconductor substrate, and inside the semiconductor substrate based on the first result value, the second result value, and the simulation data while a separation distance from the semiconductor substrate is changed.
